(19) United States
(12) Patent Application Publication
(10) Pub. No.: US 2025/0126825 A1
(43) Pub. Date: Apr. 17, 2025

(54) DUAL GATE HIGH ELECTRON MOBILITY TRANSISTOR AND METHOD OF MANUFACTURING THE SAME

(71) Applicant: National Yang Ming Chiao Tung University, Hsinchu City (TW)

(72) Inventors: Heng-Tung HSU, Taichung City (TW); Ping-Hsun CHIU, Kaohsiung City (TW)

(21) Appl. No.: 18/403,244

(22) Filed: Jan. 3, 2024

(30) Foreign Application Priority Data
Oct. 12, 2023 (TW) 112139038

(51) Int. Cl. H01L 29/778; H01L 23/31; H01L 29/20; H01L 29/423; H01L 29/66

(52) U.S. Cl. CPC H10D 30/475; H01L 23/3171; H10D 30/015; H10D 62/8503; H10D 64/411

(57) ABSTRACT

A dual gate high electron mobility transistor (HEMT) includes a substrate, a channel layer above the substrate, a source electrode, a drain electrode, a first gate electrode, and a second gate electrode. The source electrode and the drain electrode are respectively electrically coupled to the channel layer and are respectively above the channel layer. The first gate electrode and the second gate electrode are respectively electrically coupled to the channel layer and are respectively above the channel layer. The first gate electrode is located between the source electrode and the drain electrode. The second gate electrode is located between the source electrode and the first gate electrode. The second gate electrode is biased with a DC voltage.

### RELATED APPLICATIONS

This application claims priority to Taiwan Application Serial Number 112139038, filed Oct. 12, 2023, the disclosures of which are incorporated herein by reference in their entireties.

### BACKGROUND

### Field of Invention

The present invention relates to a dual gate high electron mobility transistor (HEMT). More particularly, the present invention relates to a dual gate HEMT with high linearity.

### Description of Related Art

The application and demand for next-generation communication systems are increasing. Audio and video transmission for personal use in daily life, Internet of Things (IOTs), and even military applications are pursuing high-speed satellite communication systems. Therefore, the requirements of data transmission volume and quality are getting higher and higher. In order to meet the standards of high transmission volume, high speed and low latency, the operating frequency of the communication system must be increased. In order to promote the development of ultra-high frequency communication systems, millimeter-wave band technology must be adopted in the future, thereby increasing the channel capacity. At the same time, more complex orthogonal frequency division multiplexing (OFDM) technology supplemented by more advanced and complex modulation technologies such as 64-QAM and 256-QAM is utilized to achieve the goal of desired high transmission rate. Data transmission in the millimeter wave band currently uses technologies such as beamforming to improve the throughput of data transmission. However, complex application scenarios allow multiple signals with similar frequencies to be fed into the system at the same time, resulting in mixing effects and the generation of harmonic signals, which has a huge impact on the linearity of the overall system, not only affecting the signal transmission quality, but also limiting the maximum output power that can be used. Therefore, next-generation communication systems must have high-frequency, high-power, and high-linearity characteristics. By increasing the linearity performance of the system, noise can be reduced and the performance can be improved.

Currently, the commonly known linearity optimization methods include circuit design implementation and component design technology. The circuit design implementation, such as Doherty Amplifier, Envelope tracking, and Dynamic biasing network, improves the linearity of the power amplifier in the radio frequency (RF) front-end system. The main disadvantage of the circuit design implementation is the increase in chip area and the relatively complexity, the circuit design implementation is not conducive to the realization of large array antenna systems. Another common method is to operate the amplifier in the linear region with a back-off manner. This method causes a significant decline in the power-added efficiency (PAE) of the overall system and thus this method is not an effective solution overall. Since the nonlinear performance of the system is mainly due to the non-ideal effects of active components, optimizing the intrinsic linearity of the components is a more fundamental approach. Published component linearity optimization includes field plate gates, transconductance (Gm) compensate, dual-channel or multi-channel, and three-dimensional configuration such as fin-like. The above technologies often come with disadvantages, including increased gate intrinsic capacitance, component size limitations or increased parasitic effects. Sacrificing the transconductance (Gm) and high-frequency response characteristics (such as cutoff frequency (f_{T}) and maximum available gain (MAG)) of components to achieve the goal of linearity optimization. This kind of performance trade-off between linearity and high-frequency operation is common in currently proposed technologies. If the maximum available gain is too low, the gain and power of the component operating at high frequency will be poor, and thus larger volume transmission requires more components. On the other hand, a low cutoff frequency means that the operable frequency range of the component is limited. Combined with the impact of subsequent packaging integration, the component no longer has the capability of RF applications. Therefore, the linearity and high-frequency operation capabilities of the conventional technology are a dilemma for the application of RF front-end configuration (i.e., a trade-off must be made between high-frequency response characteristics and linearity). When implementing a high-linearity power amplifier, the high-frequency characteristics cannot meet the requirements of the next-generation communication system, which places certain limitations on high-speed transmission.

### SUMMARY

In order to solve the aforementioned problem, the present invention proposes a device: a dual gate high electron mobility transistor (HEMT) with a dual gate configuration. Another gate electrode is added to be placed between a gate electrode and a source electrode of the device (also called source-RF gate access region) and is biased with a fixed DC voltage. This DC voltage changes the transmission speed characteristics of electrons within the channel of the device, such that the transconductance (Gm) curve of the device is flatter and is less affected by harmonics, and thus the linearity performance of the device is better. At the same time, the high-frequency response characteristics of the device can match the conventional single gate configuration. Through the present invention, the linearity of the device can be greatly improved, and the high-frequency application capability of the device can also be maintained. Therefore, the linearity of the radio frequency (RF) front-end module can be improved, and the present invention has the feasibility of ultra-high frequency applications, thereby improving the performance of next-generation communication systems.

The present invention provides a dual gate high electron mobility transistor (HEMT) includes a substrate, a channel layer above the substrate, a source electrode, a drain electrode, a first gate electrode, and a second gate electrode. The source electrode and the drain electrode are respectively electrically coupled to the channel layer and are respectively above the channel layer. The first gate electrode and the second gate electrode are respectively electrically coupled to the channel layer and are respectively above the channel layer. The first gate electrode is located between the source electrode and the drain electrode. The second gate electrode is located between the source electrode and the first gate electrode. The second gate electrode is biased with a DC voltage.

In accordance with one or more embodiments of the invention, the DC voltage is fixed and positive.

In accordance with one or more embodiments of the invention, the first gate electrode is a radio frequency (RF) gate for receiving a radio frequency (RF) signal.

In accordance with one or more embodiments of the invention, a linearity of the dual gate HEMT is related to a voltage value that the DC voltage has.

In accordance with one or more embodiments of the invention, the DC voltage has a voltage value greater than 3 volts.

In accordance with one or more embodiments of the invention, a linearity of the dual gate HEMT is related to a distance between the first gate electrode and the second gate electrode.

In accordance with one or more embodiments of the invention, a distance between the first gate electrode and the second gate electrode is in a range of about 0.25 micrometers to about 0.65 micrometers.

In accordance with one or more embodiments of the invention, the channel layer includes a doped GaN layer and a unintentionally doped (UID) GaN layer above the doped GaN layer. The doped GaN layer is doped with iron or carbon. The UID GaN layer has a two-dimensional electron gas (2DEG) channel therein.

In accordance with one or more embodiments of the invention, the dual gate HEMT further includes a barrier layer above the channel layer and below the first gate electrode and the second gate electrode.

In accordance with one or more embodiments of the invention, the dual gate HEMT further includes a passivation layer above the barrier layer and in contact with the barrier layer. The passivation layer has a first opening and a second opening to expose the barrier layer. The first opening and the second opening respectively accommodate the first gate electrode and the second gate electrode.

The present invention further provides a method of manufacturing a dual gate high electron mobility transistor (HEMT) includes: providing a substrate; providing a channel layer above the substrate; providing a source electrode and a drain electrode respectively electrically coupled to the channel layer and respectively above the channel layer; providing a first gate electrode and a second gate electrode respectively electrically coupled to the channel layer and respectively above the channel layer. The first gate electrode is located between the source electrode and the drain electrode. The second gate electrode is located between the source electrode and the first gate electrode. The second gate electrode is biased with a DC voltage.

In accordance with one or more embodiments of the invention, the DC voltage is fixed and positive.

In accordance with one or more embodiments of the invention, the first gate electrode is a radio frequency (RF) gate for receiving a radio frequency (RF) signal.

In accordance with one or more embodiments of the invention, a linearity of the dual gate HEMT is related to a voltage value that the DC voltage has.

In accordance with one or more embodiments of the invention, the DC voltage has a voltage value greater than 3 volts.

In accordance with one or more embodiments of the invention, a linearity of the dual gate HEMT is related to a distance between the first gate electrode and the second gate electrode.

In accordance with one or more embodiments of the invention, a distance between the first gate electrode and the second gate electrode is in a range of about 0.25 micrometers to about 0.65 micrometers.

In accordance with one or more embodiments of the invention, the channel layer includes a doped GaN layer and a unintentionally doped (UID) GaN layer above the doped GaN layer. The doped GaN layer is doped with iron or carbon. The UID GaN layer has a two-dimensional electron gas (2DEG) channel therein.

In accordance with one or more embodiments of the invention, the method of manufacturing the dual gate HEMT further includes: providing a barrier layer above the channel layer and below the first gate electrode and the second gate electrode.

In accordance with one or more embodiments of the invention, the method of manufacturing the dual gate HEMT further includes: providing a passivation layer above the barrier layer and in contact with the barrier layer. The passivation layer has a first opening and a second opening to expose the barrier layer. The first opening and the second opening respectively accommodate the first gate electrode and the second gate electrode.

### BRIEF DESCRIPTION OF THE DRAWINGS

The patent or application file contains at least one drawing executed in color. The disclosure can be more fully understood by reading the following detailed description of the embodiment, with reference made to the accompanying drawings as follows.

FIG. 1 illustrates a diagram of a dual gate high electron mobility transistor (HEMT) according to some embodiments of the present invention.

FIG. 2 shows the experimental results of the GVS performance of the dual gate HEMT as the distance de changes and the DC biased voltage changes.

FIG. 3 shows a comparison diagram of the transconductance (Gm) curves of the conventional single gate HEMT and the dual gate HEMT of the present invention.

FIG. 4 is a comparison diagram of the Gm₃ characteristics of the conventional single gate HEMT and the dual gate HEMT of the present invention.

FIG. 5 shows the characteristics of IP3 of the conventional single gate HEMT and the dual gate HEMT of the present invention at different drain-source leakage current.

FIG. 6A is a current gain diagram of a conventional single gate HEMT and the dual gate HEMT of the present invention.

FIG. 6B is a maximum available gain (MAG) diagram of a conventional single gate HEMT and the dual gate HEMT of the present invention.

FIG. 7A shows the large signal characteristics of a conventional single gate HEMT.

FIG. 7B shows the large signal characteristics of a dual gate HEMT of the present invention.

FIG. 8 shows the results of the conventional single gate HEMT and the dual gate HEMT of the present invention under test conditions with a center frequency of 38 GHz and a dual-frequency difference of 1 MHz.

FIG. 9A shows the amplitude-amplitude (AM-AM) distortion characteristics caused by the parasitic reactance effect of the conventional single gate HEMT and the dual gate HEMT of the present invention.

FIG. 9B shows the amplitude-phase (AM-PM) distortion characteristics caused by the parasitic reactance effect of the conventional single gate HEMT and the dual gate HEMT of the present invention.

### DETAILED DESCRIPTION

Specific embodiments of the present invention are further described in detail below with reference to the accompanying drawings, however, the embodiments described are not intended to limit the present invention and it is not intended for the description of operation to limit the order of implementation. Moreover, any device with equivalent functions that is produced from a structure formed by a recombination of elements shall fall within the scope of the present invention. Additionally, the drawings are only illustrative and are not drawn to actual size. The using of “first”, “second”, “third”, etc. in the specification should be understood for identify units or data described by the same terminology, but are not referred to particular order or sequence.

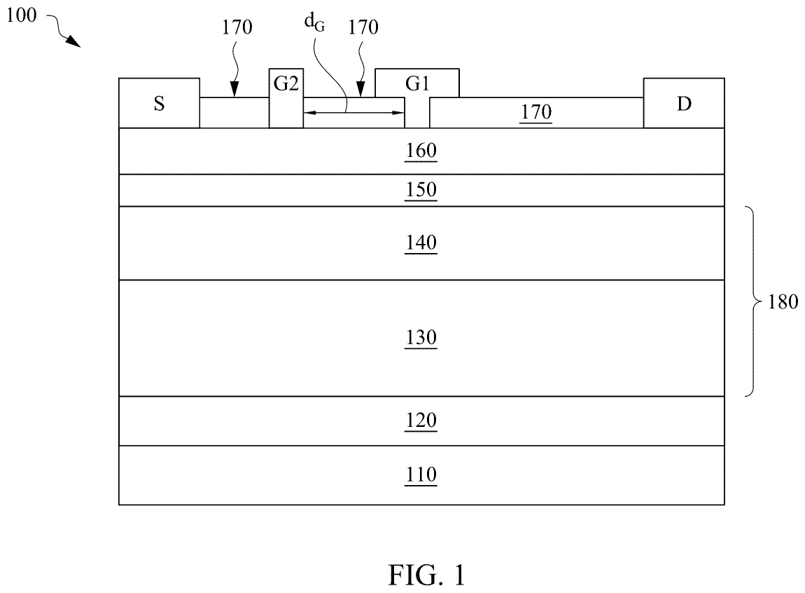

FIG. 1 illustrates a diagram of a dual gate high electron mobility transistor (HEMT) 100 according to some embodiments of the present invention. The dual gate HEMT 100 includes a substrate 110, a nucleation layer 120, a doped gallium nitride (GaN) layer 130, a unintentionally doped (UID) GaN layer 140, a spacer layer 150, a barrier layer 160, a passivation layer 170, a source electrode S, a drain electrode D, a first gate electrode G1, and a second gate electrode G2.

In some embodiments of the present invention, the substrate 110 includes silicon carbide (SiC), but the present invention is not limited thereto. In some other embodiments of the present invention, the substrate 110 includes aluminum nitride (AlN), silicon (Si), sapphire, diamond, or the like.

In some embodiments of the present invention, the nucleation layer 120 is above the substrate 110 and is AlN nucleation layer. In addition, in some other embodiments of the present invention, the dual gate HEMT 100 may not include the nucleation layer 120.

In some embodiments of the present invention, the doped GaN layer 130 is above the nucleation layer 120 and is Fe-doped GaN layer or C-doped GaN layer. In other words, the doped GaN layer 130 is doped with iron (Fe) or carbon (C). In some embodiments of the present invention, the UID GaN layer 140 is above the doped GaN layer 130 and has a thickness between about 0.2 micrometers (μm) to about 1 μm. In the preferred embodiment of the present invention, the thickness of the UID GaN layer 140 is 0.65 μm.

In some embodiments of the present invention, the doped GaN layer 130 and the UID GaN layer 140 form the channel layer 180 (also called a GaN channel layer or a GaN buffer layer) of the dual gate HEMT 100, and the channel layer 180 is above the substrate 110, and the nucleation layer 120 is between the substrate 110 and the channel layer 180. There is a two-dimensional electron gas (2DEG) channel (not shown) formed at a junction (heterojunction of the channel layer 180) close to the barrier layer 160. In other words, the UID GaN layer 140 has the 2DEG channel therein.

In some embodiments of the present invention, the spacer layer 150 is above the channel layer 180 (i.e., the channel layer 180 is between the spacer layer 150 and the nucleation layer 120) and is AlN spacer layer. The spacer layer 150 has a thickness between about 0 nanometer (nm) and about 2 nm. In the preferred embodiment of the present invention, the thickness of the spacer layer 150 is 1 nm. In other words, the dual gate HEMT 100 may not include the spacer layer 150 (i.e., a thickness of 0 nm).

In some embodiments of the present invention, the barrier layer 160 is above the spacer layer 150 (i.e., the spacer layer 150 is between the channel layer 180 and the barrier layer 160) and has a thickness between about 8 nm and about 30 nm. In the preferred embodiment of the present invention, the thickness of the barrier layer 160 is 20 nm. The barrier layer 160 includes aluminum gallium nitride (Al_{X}Ga_{1-X}N), where X is in a range from about 15% to 30%.

In some embodiments of the present invention, the passivation layer 170, the source electrode S, the drain electrode D, the first gate electrode G1 and the second gate electrode G2 are, respectively, in contact with the barrier layer and are respectively located on an upper surface of the barrier layer 160. In other words, the passivation layer 170, the source electrode S, the drain electrode D, the first gate electrode G1 and the second gate electrode G2 are above the barrier layer 160. In other words, the barrier layer 160 are below the first gate electrode G1 and the second gate electrode G2.

In some embodiments of the present invention, the passivation layer 170 is above the barrier layer 160 and is in contact with the barrier layer 160. As shown in FIG. 1, the passivation layer 170 has a first opening and a second opening to expose the barrier layer 160, such that the first opening and the second opening respectively accommodate the first gate electrode G1 and the second gate electrode G2. The passivation layer 170 includes silicon nitride (SiN). In some other embodiments of the present invention, the dual gate HEMT 100 may further includes a GaN cap layer located between the barrier layer 160 and the passivation layer 170, and the GaN cap layer has a thickness between about 0 nm and about 3 nm.

The dual gate HEMT 100 includes the source electrode S and the drain electrode D having ohmic contacts with opposite terminals/ends of the 2DEG channel of the channel layer 180. In other words, the source electrode S is electrically coupled to the 2DEG channel of the channel layer 180 and is above the channel layer 180. The drain electrode D is electrically coupled to the 2DEG channel of the channel layer 180 and is above the channel layer 180. In addition, in some other embodiments of the present invention, the source electrode S and the drain electrode D may also be above the channel layer 180 and in contact with the channel layer 180.

The first gate electrode G1 is between the source electrode S and the drain electrode D. In some embodiments of the present invention, the first gate electrode G1 is an input terminal for high-frequency signal, that is, the first gate electrode G1 is a radio frequency gate (RF Gate) for receiving high-frequency RF signals, so as to control the dual Gate HEMT 100 to be turned on or off. The first gate electrode G1 is made of nickel, gold or nickel-gold alloy. Depending on the voltage applied to the first gate electrode G1, the source electrode S and the drain electrode D are conductively coupled to each other via the 2DEG channel of the channel layer 180. In other words, the first gate electrode G1 is electrically coupled to the 2DEG channel of the channel layer 180 and is above the channel layer 180.

The second gate electrode G2 is between the source electrode S and the first gate electrode G1. In some embodiments of the present invention, the second gate electrode G2 is an input terminal biased with a DC voltage, that is, the second gate electrode G2 is a DC gate and is biased with the DC voltage. The DC voltage is a fixed voltage and its voltage value is positive. In other words, the second gate electrode G2 is continuously biased with a fixed DC voltage. The second gate electrode G2 is made of nickel, gold or nickel-gold alloy.

Through actual measurements, it was found that the linearity of the dual gate HEMT 100 is related to the voltage value of the DC voltage for biasing the second gate electrode G2. The linearity of the dual gate HEMT 100 is better when the voltage value of the DC voltage for biasing the second gate electrode G2 is greater than 1 volt.

Through actual measurements, it was found that the linearity of the dual gate HEMT 100 is related to the distance da between the first gate electrode G1 and the second gate electrode G2. The linearity of the dual gate HEMT 100 is better when the distance da between the first gate electrode G1 and the second gate electrode G2 is about 0.25 μm and about 0.65 μm.

Specifically, the present invention adds a DC gate electrode to be placed between the source electrode and the RF gate electrode to form a dual gate configuration. The DC biased voltage of the DC gate electrode is utilized to change the transmission speed characteristics of electrons between the source electrode (i.e., the source electrode S) and the high-frequency gate electrode (i.e., the first gate electrode G1) within the channel of the dual gate HEMT 100, such that the transconductance (Gm) curve of the device is flatter and is less affected by harmonics, and thus the linearity performance of the device is better. At the same time, the high-frequency response characteristics of the dual gate HEMT 100 can match the conventional single gate configuration so as to maintain its high-frequency response characteristics.

The dual gate HEMT 100 of the present invention can enable the RF front-end module to meet high-frequency requirements while improving linearity, so the dual gate HEMT 100 is more suitable for next-generation communication systems. According to the experimental results, the channel electron velocity of the dual gate HEMT 100 of the present invention can be adjusted to a relatively smoothly changing transmission characteristic, thereby improving the linearity of the device. The dual gate HEMT 100 of the present invention can be applied to the next-generation communication system architecture, and even to higher-frequency communication systems in the future. The dual gate HEMT 100 of the present invention can effectively improve the system distortion caused by complex signals and can also maintain high-frequency response characteristics. Compared with the currently known single gate HEMT, the process design of the present invention is relatively simple, and only one additional gate electrode is required.

As shown in FIG. 1, a method of manufacturing a dual gate HEMT 100 includes: providing a substrate 110; providing a channel layer 180 above the substrate 110; providing a source electrode S and a drain electrode D respectively electrically coupled to the channel layer 180 and respectively above the channel layer 180; and providing a first gate electrode G1 and a second gate electrode G2 respectively electrically coupled to the channel layer 180 and respectively above the channel layer 180. The first gate electrode G1 is located between the source electrode S and the drain electrode D. The second gate electrode G2 is located between the source electrode S and the first gate electrode G1. The second gate electrode G2 is biased with a DC voltage.

The following will use multiple actual measurement results to illustrate that the dual gate HEMT 100 of the present invention has excellent linearity performance compared to the conventional single gate HEMT and can maintain its high-frequency response characteristics at the same time.

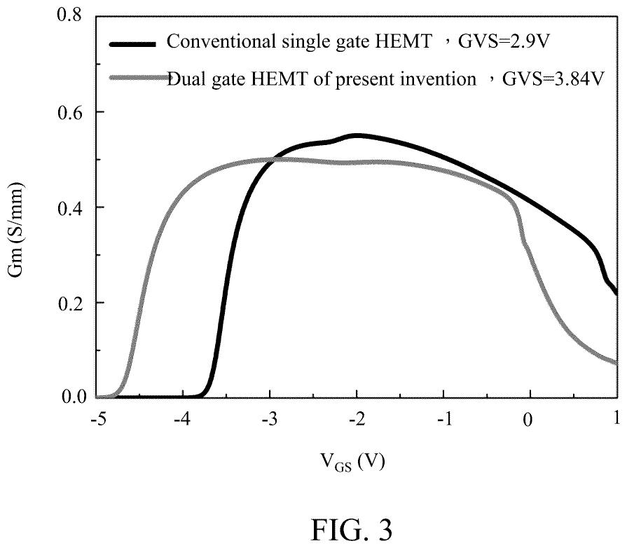

The linearity of the device is directly proportional to the flatness of the transconductance (Gm) curve of the device, because the flatter the transconductance (Gm) curve is, the more linear the drain current−the gate biased voltage (I_{D}−V_{G}) of the device is. When a signal is input to the device, the gate bias voltage (i.e., the gate-source voltage, represented by V_{G3} in FIG. 3) will float. At the same time, the current and transconductance of the device will also change with the input signal. If the transconductance curve is flatter, the current change will be more linear, and thus the linearity of the device will be better. Gate voltage swing (GVS) is an indicator for judging the linearity performance of the device. The GVS is defined as a range of the gate biased voltage corresponding to the transconductance (Gm) value decreases from its peak value to 80% with respect to the transconductance (Gm) curve. The greater the GVS is, the better the linearity of the device is.

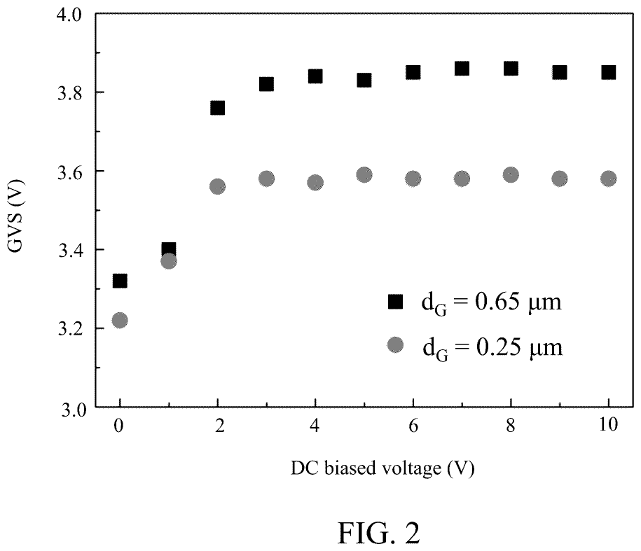

A better linearity of the dual gate HEMT 100 of the present invention can be obtained by adjusting the DC biased voltage of the second gate electrode G2 and adjusting the distance de between the first gate electrode G1 and the second gate electrode G2. FIG. 2 shows the experimental results of the GVS performance of the dual gate HEMT 100 as the distance da changes and the DC biased voltage changes. According to FIG. 2, it can be seen that when the DC biased voltage of the second gate electrode G2 of the dual gate HEMT 100 is greater than 1 volts, the GVS will be significantly improved, and when the distance dG is 0.25 μm and 0.65 μm, the GVS will be also improved. The GVS at the distance de of 0.65 μm is better than the GVS at the distance de of 0.25 μm.

FIG. 3 shows a comparison diagram of the transconductance (Gm) curves of the conventional single gate HEMT and the dual gate HEMT 100 of the present invention. As shown in FIG. 3, compared with the conventional single gate HEMT, the dual gate HEMT of the present invention has a relatively flat transconductance (Gm) curve. According to calculations, the GVS of the dual gate HEMT 100 of the present invention is 3.84 volts, which is 32% higher than the GVS of the conventional single gate HEMT of 2.9 volts, which represents that the linearity of the dual gate HEMT 100 of the present invention is better than the linearity of the conventional single gate HEMT.

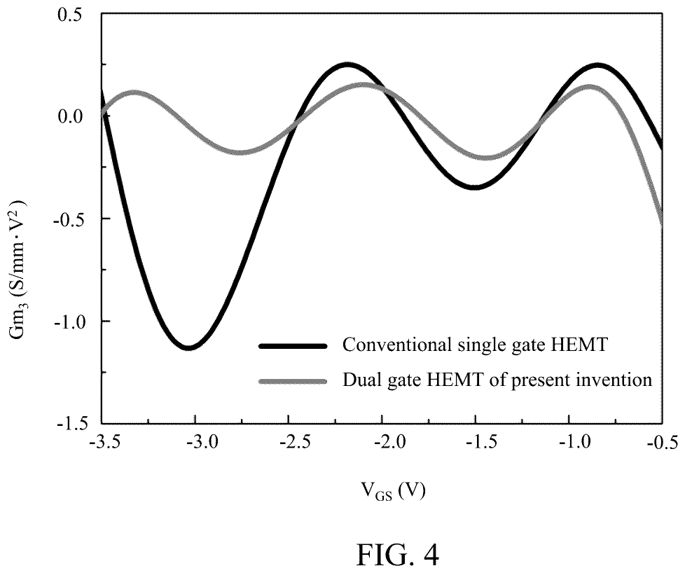

Besides the GVS, there are other indicators for judging the linearity of the device, such as third order transconductance (Gm₃). The Gm₃ of the device is defined by the following formula (1). Since the linearity of the device is inversely proportional to the third order intermodulation signal (IM3), and the Gm₃ is positively correlated with the IM3, the smaller the Gm₃ is, the better the linearity of the device is. FIG. 4 is a comparison diagram of the Gm₃ characteristics of the conventional single gate HEMT and the dual gate HEMT 100 of the present invention. It can be seen from FIG. 4 that the dual gate HEMT 100 of the present invention has relative smaller Gm₃ amplitude, and it can be inferred that its linearity is therefore better.

$$G {m}_{3} = \frac{\partial }{\partial {V}_{GS}^{2}} G m \qquad ( 1 )$$

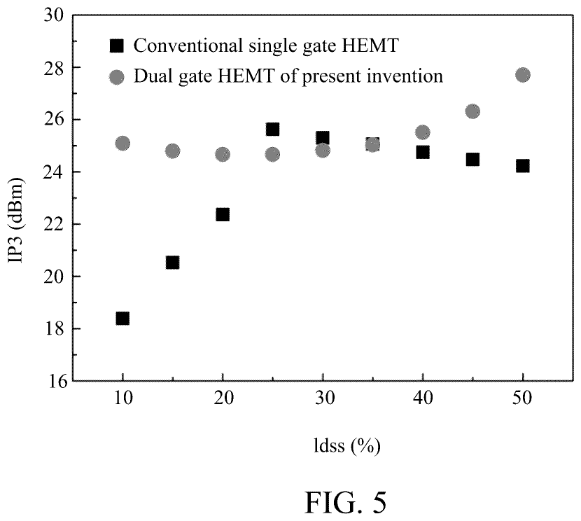

In addition, the third order intercept point (IP3) describes the value of the third-order modulation signal when the third-order modulation signal of the device and the main frequency signal of the device reach the same size. The larger the IP3 is, the better the linearity of the device is. Based on the calculation of polynomial and dual-frequency test conditions, the IP3 is defined as the following formula (2), where Gas is the output conductance and R_{L} is the load impedance. FIG. 5 shows the characteristics of IP3 of the conventional single gate HEMT and the dual gate HEMT 100 of the present invention at different drain-source leakage current (Idss, or also called saturation current). It can be found from FIG. 5 that the dual gate HEMT 100 of the present invention has better overall linearity performance and is more suitable for applications in systems with high linearity requirements.

$$IP 3 = \frac{4}{3} \cdot \frac{{( G m )}^{3}}{G {m}_{3} \cdot {G}_{d s} \cdot {R}_{L}} \qquad ( 2 )$$

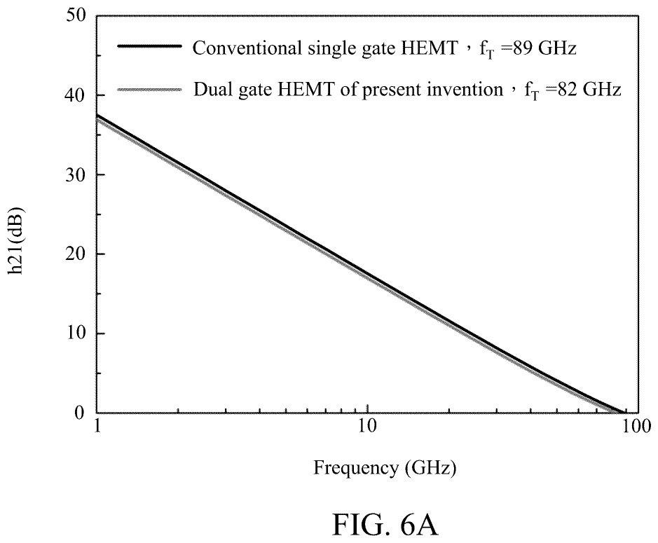

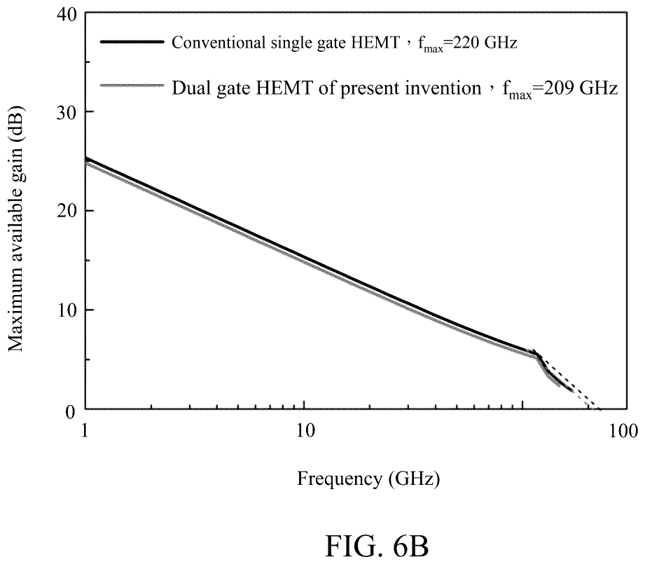

On the other hand, the high-frequency response characteristics of the device will also affect its characteristics when applied to high-frequency systems. Therefore, the present invention also tests the current gain (h21), the maximum available gain (MAG), the cutoff frequency (f_{T}) corresponding to the h21, and the maximum oscillation frequency (fₘₐₓ) corresponding to the MAG of the conventional single gate HEMT and the dual gate HEMT 100 of the present invention. Both the conventional single gate HEMT and the dual gate HEMT 100 of the present invention are operated at the transconductance (Gm) peak, and the device width is 250 μm for fair comparison. FIG. 6A is a current gain diagram of a conventional single gate HEMT and the dual gate HEMT 100 of the present invention. As shown in FIG. 6A, the initial gain of the dual gate HEMT 100 of the present invention is slightly lower than the initial gain of the conventional single gate HEMT. This is due to the lower transconductance (Gm) peak, but its cut-off frequency (f_{T}) is only 7 GHz lower, which has almost no impact. The performance of the MAG is shown in FIG. 6B. As shown in FIG. 6B, the high-frequency capability of the dual gate HEMT 100 of the present invention is not significantly lower than that of the conventional single gate HEMT.

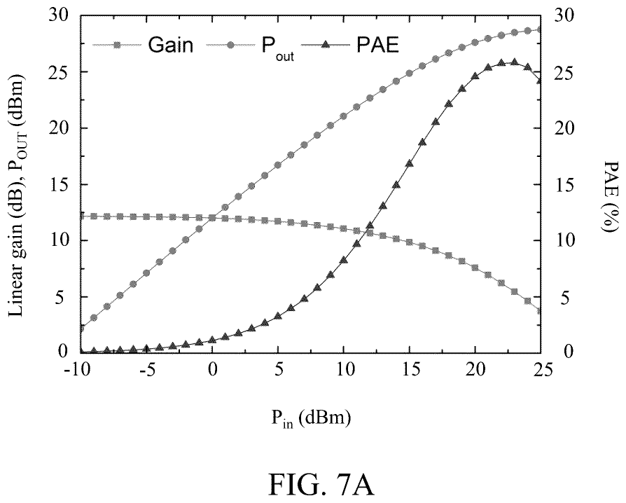

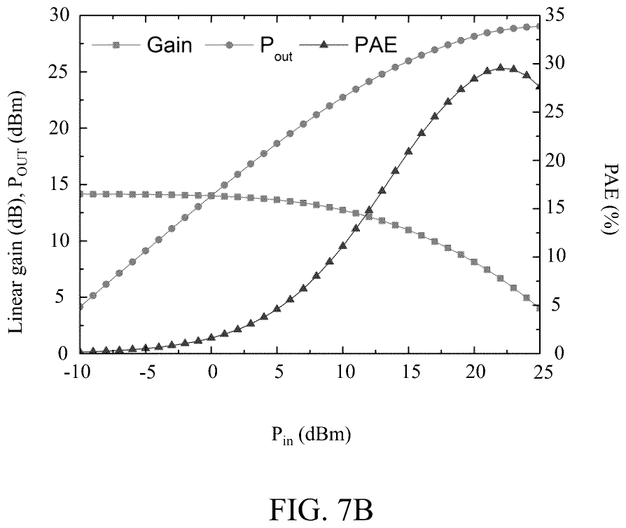

The aforementioned small-signal characteristics illustrate that the dual gate HEMT 100 of the present invention has excellent high-frequency application capabilities, and the high-frequency large-signal characteristics of the device can directly correspond to its performance in applications, such as large-signal power sweep, which can compare the linear gain, output power and power-added efficiency (PAE) of the device. FIG. 7A shows the large signal characteristics of a conventional single gate HEMT. FIG. 7B shows the large signal characteristics of a dual gate HEMT 100 of the present invention. The device is operated at a Class-AB biased voltage and the frequency is 38 GHZ. This large-signal characteristic is extracted using the Angelov GaN HEMT large-signal model, and load-pull and large-signal simulations are performed in the high-frequency circuit design software Keysight ADS. As shown in FIG. 7A and FIG. 7B, the linear gain, the saturation output power and the PAE of the dual gate HEMT 100 of the present invention are all better than those of the conventional single gate HEMT, which is sufficient to prove that the dual gate HEMT 100 of the present invention has high-frequency response characteristics.

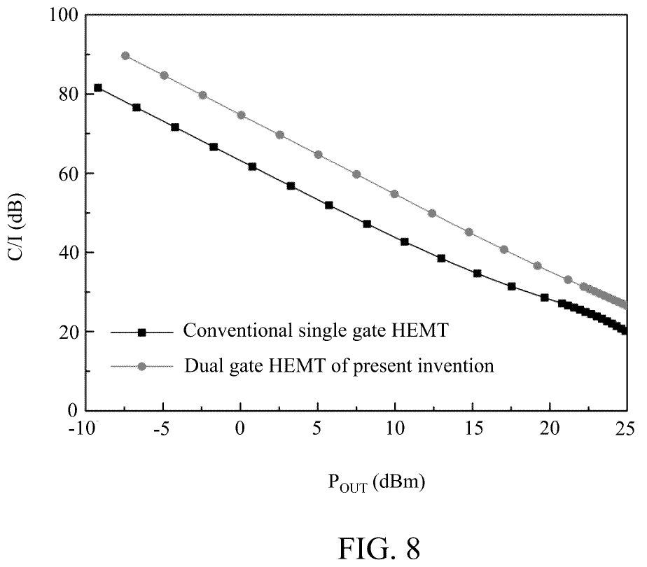

This present invention also conducts a two-tone test on the conventional single gate HEMT and the dual gate HEMT 100 of the present invention. The concept is to input two signal with similar frequencies into the device to observe the distortion ratio of the device under such complex conditions. The main frequency is usually utilized to quantify the proportion of interactive modulation signals, and its name is carrier to intermodulation ratio (C/I ratio). The higher the C/I ratio value, the lower the distortion produced by the device when inputting dual-frequency signals, which means the linearity is better. FIG. 8 shows the results of the conventional single gate HEMT and the dual gate HEMT 100 of the present invention under test conditions with a center frequency of 38 GHZ and a dual-frequency difference of 1 MHz. It can be seen from FIG. 8 that the dual gate HEMT 100 of the present invention has an optimization of C/I ratio close to 10 dB, indicating that the dual-gate HEMT 100 of the present invention can maintain excellent linearity performance in a complex operating environment.

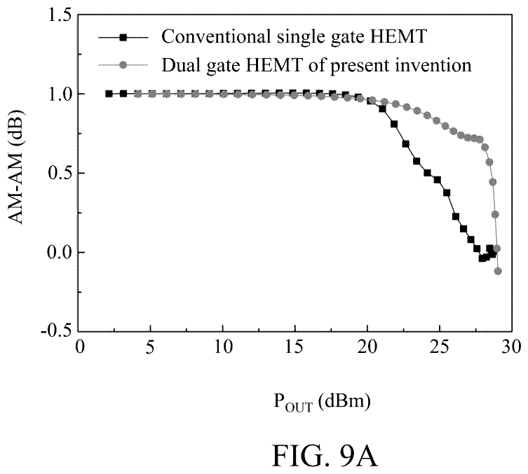

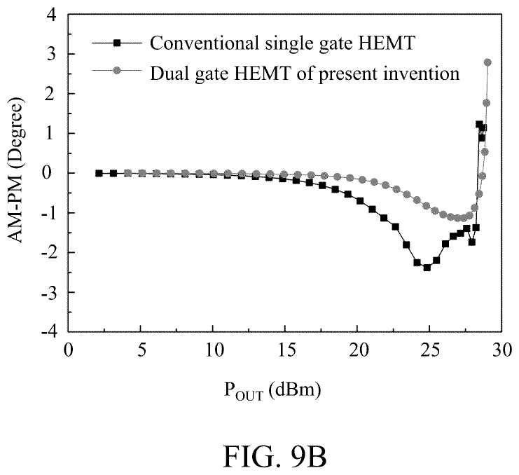

The amplitude-amplitude (AM-AM) distortion and amplitude-phase (AM-PM) distortion characteristics caused by the parasitic reactance effect of the conventional single gate HEMT and the dual gate HEMT 100 of the present invention are shown in FIG. 9A and FIG. 9B. The operating frequency is also set at 28 GHz. It can be seen from FIG. 9A and FIG. 9B that the AM-AM distortion and AM-PM distortion of the conventional single gate HEMT occur significantly earlier, while the distortion of the dual gate HEMT 100 of the present invention only occurs at higher output power (Pout), which means that the linearity performance of the dual gate HEMT 100 of the present invention is better than that of the conventional single gate HEMT.

Based on the above linearity indicators (see FIGS. 2-5), the performance of the dual gate HEMT 100 of the present invention is better than that of the conventional single gate HEMT. Based on the above high-frequency response characteristics (as shown in FIGS. 6A, 6B, 7A, 7B, 8, 9A and 9B), the high-frequency response characteristics of the dual gate HEMT 100 of the present invention is also similar to those of the conventional single gate HEMT, and the. The dual gate HEMT 100 of the present invention has the cut-off frequency similar to the cut-off frequency of the conventional single gate HEMT.

To sum up, the present invention proposes a dual gate HEMT configuration that can achieve high linearity and maintain high-frequency response capabilities. The biased operations of the two gate electrodes are separated. One of two gate electrodes is the RF gate for inputting high-frequency signal, and the other one of the two gate electrodes is the DC gate placed between the high-frequency gate electrode (RF gate) and the source electrode and is operated at a forward-biased DC bias voltage, so that the transmission speed of electrons of the device becomes more linear with the change of the biased voltage of the high-frequency gate electrode (RF gate). The present invention can further improve the flatness and linearity of the transconductance (Gm) of the device. The present invention can realize RF front-end active components to meet high linearity requirements while maintaining high frequency capabilities.

Although the present invention has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A dual gate high electron mobility transistor (HEMT), comprising:
a substrate;
a channel layer above the substrate;
a source electrode electrically coupled to the channel layer and above the channel layer;
a drain electrode electrically coupled to the channel layer and above the channel layer;
a first gate electrode electrically coupled to the channel layer and above the channel layer; and
a second gate electrode electrically coupled to the channel layer and above the channel layer
wherein the first gate electrode is located between the source electrode and the drain electrode, wherein the second gate electrode is located between the source electrode and the first gate electrode, wherein the second gate electrode is biased with a DC voltage.

2. The dual gate HEMT of claim 1, wherein the DC voltage is fixed and positive.

3. The dual gate HEMT of claim 1, wherein the first gate electrode is a radio frequency (RF) gate for receiving a radio frequency (RF) signal.

4. The dual gate HEMT of claim 1, wherein a linearity of the dual gate HEMT is related to a voltage value that the DC voltage has.

5. The dual gate HEMT of claim 1, wherein the DC voltage has a voltage value greater than 3 volts.

6. The dual gate HEMT of claim 1, wherein a linearity of the dual gate HEMT is related to a distance between the first gate electrode and the second gate electrode.

7. The dual gate HEMT of claim 1, wherein a distance between the first gate electrode and the second gate electrode is in a range of about 0.25 micrometers to about 0.65 micrometers.

8. The dual gate HEMT of claim 1, wherein the channel layer comprises:
a doped GaN layer doped with iron or carbon; and
a unintentionally doped (UID) GaN layer above the doped GaN layer and having a two-dimensional electron gas (2DEG) channel therein.

9. The dual gate HEMT of claim 1, further comprising:
a barrier layer above the channel layer and below the first gate electrode and the second gate electrode.

10. The dual gate HEMT of claim 9, further comprising:
a passivation layer above the barrier layer and in contact with the barrier layer, wherein the passivation layer has a first opening and a second opening to expose the barrier layer, wherein the first opening and the second opening respectively accommodate the first gate electrode and the second gate electrode.

11. A method of manufacturing a dual gate high electron mobility transistor (HEMT), comprising:
providing a substrate;
providing a channel layer above the substrate;
providing a source electrode and a drain electrode respectively electrically coupled to the channel layer and respectively above the channel layer; and
providing a first gate electrode and a second gate electrode respectively electrically coupled to the channel layer and respectively above the channel layer;
wherein the first gate electrode is located between the source electrode and the drain electrode, wherein the second gate electrode is located between the source electrode and the first gate electrode, wherein the second gate electrode is biased with a DC voltage.

12. The method of manufacturing the dual gate HEMT of claim 11, wherein the DC voltage is fixed and positive.

13. The method of manufacturing the dual gate HEMT of claim 11, wherein the first gate electrode is a radio frequency (RF) gate for receiving a radio frequency (RF) signal.

14. The method of manufacturing the dual gate HEMT of claim 11, wherein a linearity of the dual gate HEMT is related to a voltage value that the DC voltage has.

15. The method of manufacturing the dual gate HEMT of claim 11, wherein the DC voltage has a voltage value greater than 3 volts.

16. The method of manufacturing the dual gate HEMT of claim 11, wherein a linearity of the dual gate HEMT is related to a distance between the first gate electrode and the second gate electrode.

17. The method of manufacturing the dual gate HEMT of claim 11, wherein a distance between the first gate electrode and the second gate electrode is in a range of about 0.25 micrometers to about 0.65 micrometers.

18. The method of manufacturing the dual gate HEMT of claim 11, wherein the channel layer comprises:
a doped GaN layer doped with iron or carbon; and
a unintentionally doped (UID) GaN layer above the doped GaN layer and having a two-dimensional electron gas (2DEG) channel therein.

19. The method of manufacturing the dual gate HEMT of claim 11, further comprising:
providing a barrier layer above the channel layer and below the first gate electrode and the second gate electrode.

20. The method of manufacturing the dual gate HEMT of claim 19, further comprising:
providing a passivation layer above the barrier layer and in contact with the barrier layer, wherein the passivation layer has a first opening and a second opening to expose the barrier layer, wherein the first opening and the second opening respectively accommodate the first gate electrode and the second gate electrode.
